(19) United States
(12) Patent Application Publication
(10) Pub. No.: US 2009/0133746 A1
(43) Pub. Date: May 28, 2009

(54) Solid-State Electrolyte Composition Containing Liquid Crystal Materials and Dye-Sensitized Solar Cells Using the Same

(76) Inventors: Sung Ho Jin, Busan (KR); Jin Kook Lee, Busan (KR); Mi Ra Kim, Busan (KR); Hyun Jeong Lee, Busan (KR)

Correspondence Address: BIRCH STEWART KOLASCH & BIRCH, PO BOX 747, FALLS CHURCH, VA, 22040-0747, US

(21) Appl. No.: 11/887,550

(22) PCT Filed: May 26, 2006
(86) PCT No.: PCT/KR2006/002025

§ 371 Date: Oct. 1, 2007

(30) Foreign Application Priority Data
May 27, 2005 (KR) 10 2005 0045008

(51) Int. Cl. H01L 31/00; H01G 9/025

(52) U.S. Cl. 136/256; 252/62.2

(57) ABSTRACT

This invention provides a solid-state electrolyte containing liquid crystal material and a solar cell using the same. According to this invention, since the solar cell includes the solid-state electrolyte containing the liquid crystal material, it does not require the use of a solvent and a sealing agent, as do conventional dye-sensitized solar cells using a liquid-state electrolyte, thus realizing a simple fabrication process. Further, the solar cell of this invention can exhibit much higher energy conversion efficiency than conventional dye-sensitized solar cells using a solid-state electrolyte.

### TECHNICAL FIELD

The present invention relates to a solar cell, and more particularly to a solid-state electrolyte containing liquid crystal material and a dye-sensitized solar cell using the same.

### BACKGROUND ART

With the continuous use of fossil fuels, environmental problems, such as global warming, occur. Further, the use of uranium causes problems related to nuclear waste disposal facilities, as well as radioactive contamination. Accordingly, because alternative energy is increasingly required, thorough research thereon is being conducted. In this regard, a solar cell using solar energy is typically exemplary.

The solar cell is a device for directly producing electricity using a light-absorbing material which is able to create electrons and holes upon radiation of light. After photoelectromotive force, capable of generating current through a chemical reaction induced by light, was first invented by Becquerel, a French physicist, in 1839, a similar phenomenon was also observed in solids such as selenium. Moreover, a silicon-based solar cell having about 6% efficiency was first developed by the Bell Institute in 1954, after which research into solar cells using inorganic silicon continued.

Such an inorganic solar cell includes a p-n junction of an inorganic semiconductor, such as silicon. Silicon used in the solar cell is classified into crystalline silicon, such as monocrystalline or polycrystalline silicon, and amorphous silicon. In particular, crystalline silicon exhibits superior energy conversion efficiency for converting solar energy to electric energy to amorphous silicon, but requires a predetermined period of time and energy to grow crystals, undesirably decreasing productivity. In the case of amorphous silicon, it has a higher ability to absorb light and is easier to form into a large area, and production is higher, compared to crystalline silicon. However, amorphous silicon is inefficient in terms of equipment due to the need for a vacuum processor. Especially, in the case of an inorganic solar cell, the fabrication cost thereof is high, and it is difficult to process and mold such a cell because it must be manufactured in a vacuum.

Thus, attempts have been made to fabricate solar cells using organic material having a photoelectromotive phenomenon, instead of silicon, which has the problems mentioned above. As such, the organic photoelectromotive phenomenon means that, when an organic material is irradiated with light, it absorbs photons of light to create electron-hole pairs, which are then separated and transported to a cathode and an anode, respectively, resulting in the generation of current through such charge flow. That is, in a typical organic solar cell, when light is radiated onto the organic material having a junction structure of an electron donor and an electron acceptor, the electron-hole pair is formed in the electron donor, and the electron is transported into the electron acceptor, thus realizing the separation of electron and hole. Such a procedure is referred to as “excitation of charge carrier using light” or “photoinduced charge transfer (PICT)”, in which the photoinduced carriers are separated into electrons and holes, and thus power is produced through an external circuit.

From the basic physical point of view, output power produced from all solar power plants including solar cells is regarded as being produced through the flow of a light exciton generated by light and a driving force. In the solar cell, the flow is related to current, and the driving force is directly related to voltage. Generally, the voltage of the solar cell is determined by the type of electrode material used, and the conversion efficiency of solar light is a value obtained by dividing the output voltage by the incident solar energy, and the total output current is determined by the number of absorbed photons.

The organic solar cell fabricated using the photoinduced phenomenon of the organic material is classified into a multilayered solar cell including a transparent electrode, a metal electrode, and layers of electron donor and electron acceptor interposed between the transparent electrode and the metal electrode, and into a monolayered solar cell including a blend of electron donor and electron acceptor.

Because the solar cell fabricated using a traditional organic material has low energy conversion efficiency and a durability problem, a dye-sensitized solar cell, which is a photoelectrochemical solar cell using a dye as a photosensitizer, has been developed by Graetzel Research, Switzerland, 1991. The photoelectrochemical solar cell proposed by Graetzel is a photoelectrochemical solar cell using an oxide semiconductor comprising photosensitive dye molecules and titanium dioxide nanoparticles.

That is, the dye-sensitized solar cell is a solar cell fabricated by inserting an electrolyte into an oxide layer, in particular, a titanium oxide layer, which is adsorbed with a dye, between the transparent electrode and the metal electrode to cause a photoelectrochemical reaction. Typically, it has been reported that the dye-sensitized solar cell, comprising two electrodes (photoelectrode and counter electrode), inorganic oxide, the dye and the electrolyte, is environmentally friendly thanks to the use of environmentally friendly material, and has high energy conversion efficiency of about 10% corresponding to that of an amorphous silicon-based solar cell among conventional inorganic solar cells, and also may be fabricated at a cost of only about 20% of that of silicon solar cells, leading to very high commercial availability.

The dye-sensitized solar cell using the photochemical reaction mentioned above has a multilayered cell structure in which an oxide layer adsorbed with dyes for absorbing light and an electrolyte layer for reducing the electrons are interposed between the cathode and the anode. The conventional dye-sensitized solar cell is briefly described as follows.

The conventional multilayered dye-sensitized solar cell is composed of substrate/electrode/dye-adsorbed titanium oxide layer/electrolyte/electrode, and specifically includes a lower substrate, an anode, a dye-adsorbed titanium oxide layer, an electrolyte layer, a cathode, and an upper substrate, which are sequentially formed upward. As such, the lower substrate and the upper substrate are formed of glass or plastic, the anode being coated with ITO (indium tin oxide) or FTO (fluorine doped tin oxide), and the cathode being coated with platinum.

According to the operation principle of the conventional dye-sensitized solar cell thus structured, when light is radiated onto the dye-adsorbed titanium oxide layer, the dye absorbs photons (electron-hole pairs) to form excitons. The excitons thus formed are transformed from a ground state into an excited state. Thereby, the electron-hole pairs are respectively separated, such that the electrons are injected into the titanium oxide layer and the holes are transported into the electrolyte layer. As such, when an external circuit is supplied, electrons are transported into the cathode via the titanium oxide layer from the anode through the lead wires, therefore generating current. Since the electrons transported to the cathode are reduced by the electrolyte, while the excited electrons are continuously transported, the current is generated.

However, a general dye-sensitized solar cell using a conventional liquid-state electrolyte has stability problems, such as deteriorated properties due to leakage of the electrolyte and evaporation of the solvent, despite having high energy conversion efficiency. In such a case, the problems are a deterrent to the realization of the commercialization of the cell. Thus, thorough research has been conducted to prevent the leakage of the electrolyte. In this regard, the dye-sensitized solar cell has been developed using a solid-state electrolyte, which is able to increase the stability and durability of the solar cell.

Attributed to the problems with the liquid-state electrolyte, a gel-state electrolyte causing the electrolyte to penetrate into the polymer has been proposed. However, the gel-state electrolyte suffers because it has high viscosity and is crosslinked by the weak interaction between polymers, and thus may be easily liquefied through a heating process.

For example, Korean Patent Laid-open Publication No. 2003-65957 discloses a dye-sensitized solar cell including polyvinylidene fluoride dissolved in N-methyl-2-pyrrolidone or 3-methoxypropionitrile serving as a solvent. Although the polymer electrolyte thus prepared has high ionic conductivity similar to that of the liquid-state electrolyte at room temperature, since it has poor mechanical properties, the cell fabrication process is complicated. Further, the liquid preservability of the polymer electrolyte is undesirably decreased.

In the case of the solar cell using a solid-state electrolyte, a solvent is removed from the electrolyte solution to compensate for low efficiency attributable to the solvent, easily reducing the electrons transported into the anode using a hole conductive material in a solid phase, leading to the re-oxidation of the dye. Thereby, current can flow.

Fabrication of a solar cell using the solid-state electrolyte without the solvent was first attempted by the De Paoli Group, Brazil, 2001, resulting in the preparation of a polymer electrolyte composed of poly(epichlorohydrin-co-ethylene oxide)/NaI/I₂ and energy efficiency of about 1.6% at 100 mW/cm². Subsequently, the Flaras Group, Greece, 2002, conducted research into the improvement of mobility of I⁻/I₃⁻ by adding titanium oxide nanoparticles to highly crystalline polyethylene oxide to decrease the crystallinity of the polymer.

Recently, in the Center for Facilitated Transport Membranes, Korea Institute of Science and Technology (KIST), Korea, 2004, effective application of low-molecular weight polyethyleneglycol (PEG) to a dye-sensitized solar cell using a hydrogen bond was studied, resulting in energy conversion efficiency of about 3.5%.

In this way, in the dye-sensitized solar cell using the solid-state electrolyte, the development of a polymer electrolyte having high ionic conductivity and the maximization of energy conversion efficiency by the increase in interfacial contact between the dye and the polymer electrolyte are regarded as important.

However, the development of a solid-state dye-sensitized solar cell able to overcome the above problems without sacrificing the solid state and ionic conductivity has not yet been realized in the art. Thus, there is a high need for the development of such a novel device in the art.

### DISCLOSURE

### Technical Problem

Accordingly, the present invention has been made keeping in mind the above problems occurring in the related art, and an object of the present invention is to provide an electrolyte suitable for use in a solar cell, in which an electrolyte solution is added with a liquid crystal compound and thus is increased with respect to the ionic conductivity even after being solidified due to the orientation of the liquid crystal, and a dye-sensitized solar cell including an electrolyte layer in which the liquid crystal material is contained in a predetermined proportion to greatly increase energy conversion efficiency.

Another object of the present invention is to provide a dye-sensitized solar cell having high efficiency, in which a dipping process is adopted in the formation of an electrolyte layer to maximize surface contact between the dye and the electrolyte layer so as to effectively induce an increase in photocurrent, and a method of fabricating the same.

A further object of the present invention is to provide a dye-sensitized solar cell, exhibiting economic benefits through a simple fabrication process by overcoming the leakage of a solvent due to the use of a conventional liquid-state electrolyte and the durability problem due to the use of a sealing agent, and a method of fabricating the same.

The above and other objects, features and advantages of the present invention will be more clearly understood from the following detailed description taken in conjunction with the accompanying drawings.

### Technical Solution

According to a first aspect of the present invention, the present invention provides a solid-state electrolyte for use in a solar cell, comprising materials represented by Formulas I to III below:

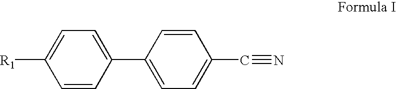

(in Formula I, R₁ is a C₁˜C₂₀ alkyl group, a C₁˜C₂₀ alkoxy group, or a C₁˜C₂₀ alkyl-substituted aryl group).

Further, the polymer liquid crystal material according to the present invention may be a siloxane-based compound represented by Formula II below or an acryl-based compound represented by Formula III below:

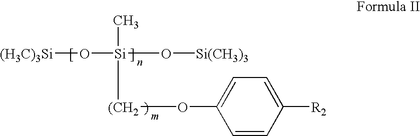

(in Formula II, R₂ is an unsubstituted or substituted aryl group, m is an integer of 1˜20, and n is an integer of 10 or more)

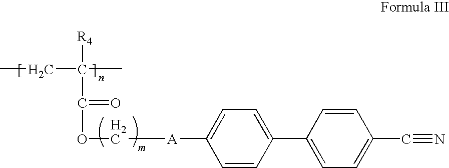

(in Formula III, R₄ is hydrogen or a C₁˜C₁₀ alkyl group, A is ether, ester, or a ketone group, m is an integer of 1˜20, and n is an integer of 10 or more).

The liquid crystal material represented by Formulas I to III may be used in a proportion of 5˜95 wt %, preferably 20˜80 wt %, and more preferably 40˜60 wt %, based on the total weight of the electrolyte.

As such, the liquid crystal material represented by Formula II or III has an average molecular weight of 5,000˜1,000,000.

According to a second aspect of the present invention, the present invention provides a solid-state dye-sensitized solar cell, in which the liquid crystal material represented by Formula I to III is added to the electrolyte layer.

The solid-state dye-sensitized solar cell of the present invention may comprise a first electrode, a second electrode facing the first electrode, and an electrolyte layer and a dye-adsorbed inorganic oxide layer interposed between the first electrode and the second electrode.

According to a third aspect of the present invention, the present invention provides a method of fabricating a solid-state dye-sensitized solar cell in which the liquid crystal material represented by Formula I to III is added to the electrolyte layer. As such, the oxide layer included in the solar cell is preferably prepared in a state of being dipped into the electrolyte solution containing the liquid crystal material.

### ADVANTAGEOUS EFFECTS

According to the present invention, since the solid-state dye-sensitized solar cell is composed of an electrolyte layer added with a liquid crystal material, it has superior stability to a conventional liquid-state dye-sensitized solar cell. Further, the problem of durability due to the loss of a solvent can be overcome, and furthermore, the added liquid crystal material functions to increase ionic conductivity, leading to greatly increased energy conversion efficiency compared to a conventional solid-state dye-sensitized solar cell.

In the present invention, in order to solve the problem of low energy conversion efficiency due to recombination caused by incomplete contact between a dye-adsorbed oxide layer and an electrolyte layer, a dipping process for dipping an electrode into an electrolyte solution is adopted to sufficiently diffuse the electrolyte solution into fine pores, therefore increasing energy conversion efficiency.

Particularly, the solid-state dye-sensitized solar cell of the present invention is superior to conventional dye-sensitized solar cells in the following ways.

First, since the dye-sensitized solar cell of the present invention is a solid-state solar cell without a solvent, compared to a conventional liquid-state dye-sensitized solar cell, the problems with the efficiency and stability of the device due to the leakage of the solvent may be solved.

Second, since the solid-state electrolyte of the present invention is added with the liquid crystal material, the ionic conductivity may be increased through the orientation of the liquid crystal material. Thereby, the dye-sensitized solar cell of the present invention can be confirmed to have greatly improved energy conversion efficiency, compared to conventional dye-sensitized solar cells which use a solid-state electrolyte.

Third, the low efficiency of the dye-sensitized solar cell due to the interfacial contact problem frequently causing the electron-hole recombination may be solved in a manner such that the electrode is dipped into an electrolyte solution, which has been previously prepared, thereby increasing the interfacial adhesion between the dye-adsorbed oxide layer and the electrolyte.

Fourth, the solid-state dye-sensitized solar cell of the present invention has maximum energy conversion efficiency of 8.9%, which is much higher than that of the conventional solid-state dye-sensitized solar cell.

### DESCRIPTION OF DRAWINGS

FIG. 1 is a cross-sectional view showing the structure of a dye-sensitized solar cell of the present invention;

FIG. 2 is a graph showing the UV-visible absorption spectrum of the oxide layer and the dye-adsorbed oxide layer manufactured in the preferred example of the present invention;

FIGS. 3 and 4 are SEM photographs showing the cross-section of the oxide layer and the dye-adsorbed oxide layer, respectively, manufactured in the preferred example of the present invention;

FIGS. 5 and 6 are SEM photographs showing the surface of the oxide layer and the dye-adsorbed oxide layer, respectively, manufactured in the preferred example of the present invention;

FIG. 7 is a graph showing the result of measurement of voltage-current density of the solid-state dye-sensitized solar cell fabricated by adding the solid-state electrolyte with E7, which is a low-molecular weight liquid crystal material, in the preferred example of the present invention;

FIG. 8 is a graph showing the result of measurement of voltage-current density of the solid-state dye-sensitized solar cell fabricated by adding the solid-state electrolyte with LCP 1, which is a siloxane-based polymer liquid crystal material, in the preferred example of the present invention;

FIG. 9 is a graph showing the result of measurement of voltage-current density of the solid-state dye-sensitized solar cell fabricated by adding the solid-state electrolyte with LCP 83, which is a siloxane-based polymer liquid crystal material, in the preferred example of the present invention;

FIG. 10 is a graph showing the result of measurement of voltage-current density of the solid-state dye-sensitized solar cell fabricated by adding the solid-state electrolyte with LCP 94, which is an acryl-based polymer liquid crystal material, in the preferred example of the present invention;

FIG. 11 is a graph showing the result of measurement of voltage-current density of the solid-state dye-sensitized solar cell fabricated by adding the solid-state electrolyte with LCP 95, which is an acryl-based polymer liquid crystal material, in the preferred example of the present invention;

FIG. 12 is a graph showing the result of measurement of voltage-current density of the solid-state dye-sensitized solar cell fabricated by adding the solid-state electrolyte with LCP 105, which is an acryl-based polymer liquid crystal material, in the preferred example of the present invention; and

FIG. 13 is a graph showing the result of measurement of voltage-current density of the solid-state dye-sensitized solar cell fabricated using the solid-state electrolyte without the addition of liquid crystal material in the comparative example.

### DESCRIPTION OF THE REFERENCE NUMERALS IN THE DRAWINGS

1001: first substrate 1002: first electrode
1003: oxide layer 1004: electrolyte layer
1005: second electrode 1006: second substrate

### BEST MODE

Hereinafter, a detailed description will be given of the present invention with reference to the appended drawings.

According to the general dye-sensitized solar cell mentioned above, while photons of light absorbed by the dye create electron-hole pairs, electrons are rapidly transferred to a dye-adsorbed oxide layer. Further, when such electrons are transferred to a cathode from an anode through an external circuit, the transferred electrons are reduced again by the electrolyte, so that current can flow. In such a dye-sensitized solar cell, since the liquid-state electrolyte is typically used, initial energy conversion efficiency is high. However, due to the leakage and volatility of the solvent or the problem with a sealing agent, the durability is decreased and the energy conversion efficiency is also lowered.

In addition, in the case of the conventional dye-sensitized solar cell using the solid-state electrolyte, although the electrolyte exhibits high conductivity in a liquid state, it is undesirably decreased with respect to ionic mobility after being solidified. Moreover, the interfacial contact area between the oxide layer and the electrolyte layer is decreased, thus the ionic conductivity is drastically decreased, leading to remarkably low energy conversion efficiency of the solar cell.

Accordingly, the present inventors have fabricated a solid-state dye-sensitized solar cell in a manner such that low-molecular weight liquid crystal material or a liquid crystal polymer, having orientation properties, is added to the electrolyte solution, whereby current is generated and the ionic mobility is increased thanks to the orientation of the liquid crystal, resulting in high energy conversion efficiency. Further, when fabricating the solar cell, adopted is a process of dipping a dye-adsorbed oxide layer into the electrolyte solution to realize interfacial contact between the oxide layer and the electrolyte.

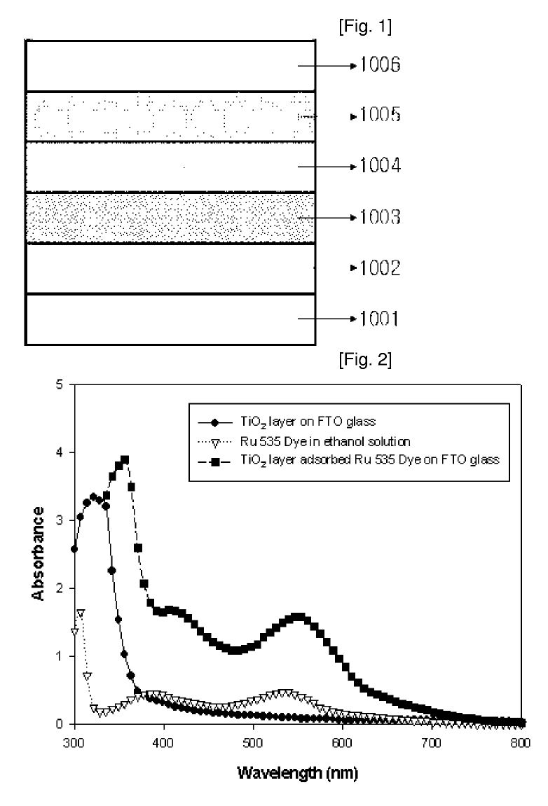

FIG. 1 is a cross-sectional view showing the solid-state dye-sensitized solar cell fabricated using a solid-state electrolyte containing liquid crystal material, according to the present invention. As shown in the drawing, the solid-state dye-sensitized solar cell has a multilayered thin film structure comprising two transparent substrates, that is, a first substrate 1001 and a second substrate 1006, a first electrode 1002 and a second electrode 1005 facing each other and provided between the two substrates, and an oxide layer 1003 and an electrolyte layer 1004 between the first electrode 1002 and the second electrode 1005.

The first substrate 1001 is formed of a transparent material, such as glass or plastic, including PET (polyethylene terephthalate), PEN (polyethylene naphthalate), PP (polypropylene), PI (polyamide), TAC (triacetyl cellulose), etc., and is preferably formed of glass.

The first electrode 1002 is an electrode formed using a transparent material on one surface of the first substrate 1001. The first electrode 1002, functioning as an anode, is formed of a material having a lower work function than that of the second electrode 1005, for example, a predetermined transparent conducting material. In the present invention, using a sputtering process or a spin coating process, the first electrode 1002 is applied on the surface of the first substrate 1001, or may be formed in the shape of a film.

In the present invention, the first electrode 1002 is formed of a material selected from among ITO (indium-tin oxide), FTO (Fluorine doped tin oxide), ZnO—(Ga₂O₃ or Al₂O₃), and SnO₂—Sb₂O₃. ITO or FTO is especially preferable.

The oxide layer 1003 is formed of inorganic oxide, and preferably transition metal oxide nanoparticles. For example, not only transition metal oxides, such as titanium oxide, scandium oxide, vanadium oxide, zinc oxide, gallium oxide, yttrium oxide, zirconium oxide, niobium oxide, molybdenum oxide, indium oxide, tin oxide, lanthanide oxide, tungsten oxide, and iridium oxide, but also alkali earth metal oxides, such as magnesium oxide and strontium oxide, and aluminum oxide, are useful. In the present invention, the material for inorganic oxide is preferably exemplified by titanium oxide nanoparticles.

The oxide layer 1003 is applied on one surface of the first electrode 1002 and is then heat treated, therefore forming it on the first electrode 1002. Commonly, using a doctor blade process or a screen printing process, a paste containing inorganic oxide is applied on the surface of the first electrode 1002 to a thickness of about 0.1˜100 μm, preferably 1˜50 μm, and more preferably 5˜30 μm. Alternatively, a spin coating process, a spray process, or a wet coating process may be used.

On the oxide layer 1003 included in the dye-sensitized solar cell of the present invention, a photosensitive dye is adsorbed. Accordingly, upon radiation of solar light, the photons of light are absorbed by the dye adsorbed on the oxide layer 1003 and thus electrons in the dye are excited, creating electron-hole pairs. When the excited electrons are injected into the conduction band of the oxide layer 1003, the injected electrons are transferred to the first electrode 1002 and then transferred to the second electrode 1005 through an external circuit. Also, the electrons transferred to the second electrode 1005 are transported to the electrolyte layer 1004 through redox of the electrolyte composition contained in the electrolyte layer 1004. On the other hand, although the dye is oxidized after the electron transfer to inorganic oxide, it receives the electrons transferred to the electrolyte layer 1004 to be reduced into the original state. Hence, the electrolyte layer 1004 functions to receive the electrons from the second electrode 1005 so as to transfer such electrons to the dye.

In the present invention, the photosensitive dye, which is chemically adsorbed on the oxide layer 1003, may include a material able to absorb UV light and visible light, that is, a ruthenium complex. Examples of the photosensitive dye adsorbed on the oxide layer 1003 include ruthenium complexes such as Ruthenium 535, Ruthenium 535 bis-TBA, or Ruthenium 620-1H3TBA. Preferably, Ruthenium 535 is useful. Moreover, the photosensitive dye chemically adsorbed on the oxide layer 1003 may include a predetermined dye having a charge separation function, for example, a xanthene-based dye, a cyanine-based dye, a porphyrin-based dye, or an anthraquinone-based dye, in addition to the ruthenium-based dye.

Further, in order to adsorb the dye on the oxide layer 1003, a typical process may be employed. Preferably, useful is a process of dipping the photoelectrode coated with the oxide layer 1003 into a solution of the dye dissolved in alcohol, nitrile, halogenated hydrocarbon, ether, amide, ester, ketone, or N-methylpyrrolidone.

In addition, the electrolyte layer 1004, formed adjacent to the oxide layer 1003, functions as a carrier transport layer. In this way, with the intention of substantially exhibiting a charge transport function, the electrolyte layer 1004 of the present invention is composed of an electrolyte composition having a redox couple and a matrix component able to prevent the leakage and volatility of the electrolyte composition. As such, the electrolyte layer 1004 may be a gel-state electrolyte composed of a solution of a redox couple dissolved in a solvent and a matrix component, or a complete solid-state electrolyte composed of a molten salt and a matrix component. In the present invention, the gel-state electrolyte is particularly preferable.

Examples of an electrolyte as the reversible redox couple contained in the electrolyte composition include, for example, a halogen redox electrolyte composed of halogen compound using a halogen ion as a counter ion/halogen molecule, an aromatic redox electrolyte such as hydroquinone/quinone, or a metal redox electrolyte such as ferrocyanate/ferricyanate or ferrocene/ferricinium ions. The halogen redox electrolyte is particularly preferable.

In the halogen redox electrolyte composed of halogen compound/halogen molecule usable as the redox couple according to the present invention, examples of the halogen molecule include iodine molecule (I₂) or bromine molecule (Br₂). In particular, the iodine molecule is preferable. Further, the halogen compound, in which the halogen ion serves as the counter ion, includes halogenated metal salts (halogenated metal compound) or halogenated organic salts (halogenated organic compound).

In the case where the redox couple dissolved in a solvent is used, the redox couple in the solvent may have a predetermined concentration. For example, the halogen compound in the solvent may have a concentration of 0.05˜5 M, and preferably 0.2˜1 M, and the halogen molecule in the solvent may have a concentration of 0.0005˜1 M, and preferably 0.001˜0.1 M. As such, the halogen compound and the halogen molecule may be mixed at a ratio able to cause a reversible redox reaction. For example, the halogen compound and the halogen molecule may be used at a weight ratio of about 0.5:1˜10:1, and preferably about 2:1˜5:1.

In the halogen redox electrolyte useful as the redox couple of the present invention, the cation of the halogenated metal compound of the halogen compound includes Li, Na, K, Mg, Ca, Ca, etc. For example, useful is a halogenated metal salt, including alkali metal iodide such as LiI, NaI, KI, or CsI, or alkali earth metal iodide such as CaI₂. Further, the redox couple of the preferable halogenated metal compound includes LiI/I₂, KI/I₂, NaI/I₂, or CsI/I₂.

In addition, examples of the cation of the halogenated organic compound constituting the redox couple include, but are not limited to, ammonium compounds, such as imidazolium, tetra-alkyl ammonium, pyridinium, pyrrolidinium, pyrazolidium, isothiazolidium, and triazolium. The halogenated organic compound usable as the redox couple according to the present invention is selected from among n-methylimidazolium iodide, n-ethylimidazolium iodide, 1-benzyl-2-methylimidazolium iodide, 1-ethyl-3-methylimidazolium iodide, 1-butyl-3-methylimidazolium iodide, 1-methyl-3-propylimidazolium iodide, 1-methyl-3-isopropylimidazolium iodide, 1-methyl-3-butylimidazolium iodide, 1-methyl-3-isobutylimidazolium iodide, 1-methyl-3-s-butylimidazolium iodide, 1-methyl-3-pentylimidazolium iodide, 1-methyl-3-isopentylimidazolium iodide, 1-methyl-3-hexylimidazolium iodide, 1-methyl-3-isohexylimidazolium iodide, 1-methyl-3-ethylimidazolium iodide, 1,2-dimethyl-3-propylimidazolium iodide, 1-ethyl-3-isopropylimidazolium iodide, 1-propyl-3-propylimidazolium iodide, and mixtures thereof. Preferably, the redox couple of the halogenated organic compound/halogen molecule according to the present invention includes trimethyl ammonium iodide/I₂ or tetraalkyl ammonium iodide/I₂, such as tetrapropyl ammonium iodide (TPAI)/I₂ or tetrabutyl ammonium iodide (TBAI)/I₂.

Although the halogenated organic compound may be used along with the halogen molecule to constitute the redox couple, it may be added to the electrolyte composition in the form of an ionic liquid without the halogen molecule. In the present invention, the halogenated organic compound used as the ionic liquid includes, for example, organic halides constituting the redox couple mentioned above, preferably alkyl imidazolium iodide, such as n-methylimidazolium iodide, n-ethylimidazolium iodide, 1-benzyl-2-methylimidazolium iodide, 1-ethyl-3-methylimidazolium iodide, or 1-butyl-3-methylimidazolium iodide, and more preferably 1-ethyl-3-methylimidazolium iodide.

Further, in the case where the redox electrolyte is used as a gel-state electrolyte, the above-mentioned redox couple may be supplied in the form of a solution thereof. In the present invention, the solvent used in the electrolyte layer 1004 functions to dissolve not only the electrolyte but also the matrix polymer acting as the binder of the matrix component mentioned below.

In the present invention, the solvent, which is electrochemically inert, is selected from among alcohol, ether, ester, lactone, nitrile, ketone, amide, halogenated hydrocarbon, dimethylsulfoxide, N-methylpyrrolidone, methoxypropionitrile, propylimidazole, hexylimidazole, pyridine, acetonitrile, methoxyacetonitrile, tetrahydrofuran, diethylether, ethyleneglycol, diethyleneglycol, triethyleneglycol, ethylene carbonate, propylene carbonate, γ-butyrolactone, dimethylformamide, diethylcarbonate, dimethylcarbonate, and mixtures thereof. Particularly, there is exemplified a combination of a fundamental solvent selected from among acetonitrile, methoxypropionitrile, methoxyacetonitrile, and ethyleneglycol and an additive solvent selected from among ethylene carbonate, propylene carbonate, diethyl carbonate, dimethyl carbonate, γ-butyrolactone, dimethylformamide and mixtures thereof. In the case where the combination of the fundamental solvent and the additive solvent is used, it may be formed at a predetermined ratio. For example, when acetonitrile is used as the fundamental solvent and ethylene carbonate/propylene carbonate are used as the additive solvent, the fundamental solvent and the additive solvent may be combined at a weight ratio of about 0.5:1˜3:1.

Moreover, the solvent may further include a plasticizer functioning to dissociate the electrolyte salt included in the electrolyte composition and improve the ion transfer. In the present invention, the preferable plasticizer is a material having a low viscosity and a high dielectric constant. Specifically, exemplary are cyclic carbonate such as ethylene carbonate (EC) or propylene carbonate (PC), chain carbonate such as dimethyl carbonate, methylethyl carbonate or dimethyl carbonate, γ-butyrolactone, methyl propionate, ethyl propionate, cyclic ether such as tetrahydrofuran or 2-methyltetrahydrofuran, chain ether such as dimethoxy ethane, diethoxy ethane or dimethylformamide, or mixtures thereof. In particular, ethylene carbonate/propylene carbonate are preferable. In the case where the mixture of ethylene carbonate and propylene carbonate is used as the additive solvent, that is, the plasticizer, it may be formed at a volume ratio of about 1:1˜10:1.

In the present invention, the electrolyte layer 1004 includes the matrix component for use in the prevention of the leakage and volatility of the liquid composition, in addition to the electrolyte composition consisting of the redox couple and the solvent. The matrix component used in the present invention includes a matrix polymer, acting as a binder, and a liquid crystal material added to the matrix polymer in a predetermined proportion.

The matrix polymer included in the matrix component of the present invention includes a material able to function as a binder, preferably a conductive polymer, such as polyaniline, polyacetylene, polythiophene, or polyphenylenevinylene, or a polymer such as polyacrylonitrile (PAN), polymethacrylate, or polyethyleneglycol (PEG). Especially, the matrix polymer functioning as the matrix is exemplified by polyacrylonitrile having a cyan group (—CN) at the terminal end thereof. Polyacrylonitrile, which is a superior conductive polymer, functions to realize interfacial contact between the electrolyte layer 1004 and the oxide layer 1003 adjacent thereto thanks to the terminal cyan group thereof. As well, polyacrylonitrile has a structure suitable for the orientation of the liquid crystal material, in particular, a low-molecular weight liquid crystal material, included in the matrix component.

In the solid-state electrolyte of the present invention, the liquid crystal material, which constitutes the matrix component along with the matrix polymer, comprises a low-molecular weight liquid crystal material represented by Formula 1 below, a siloxane-based polymer liquid crystal material represented by Formula 2 below, or an acryl-based polymer liquid crystal material represented by Formula 3 below, added in predetermined proportions. The liquid crystal material represented by Formulas I to III may be used in a proportion of 5˜95 wt %, preferably 20˜80 wt %, and more preferably 40˜60 wt %, based on the total weight of the matrix component:

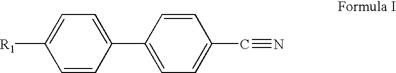

(in Formula I, R₁ is a C₁˜C₂₀ alkyl group, a C₁˜C₂₀ alkoxy group, or a C₁˜C₂₀ alkylaryl group)

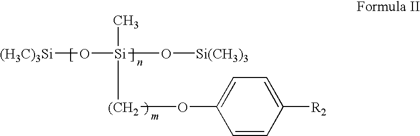

(in Formula II, R₂ is an unsubstituted or substituted aryl group, m is an integer of 1˜20, and n is an integer of 10 or more)

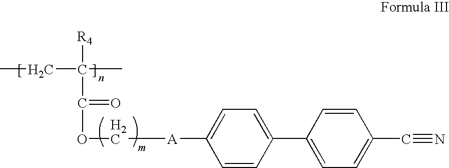

(in Formula III, R₄ is hydrogen or a C₁˜C₁₀ alkyl group, A is ether, ester, or a ketone group, m is an integer of 1˜20, and n is an integer of 10 or more).

The liquid crystal material, which is added to the electrolyte layer 1004 of the present invention, is specifically described below. The low-molecular weight liquid crystal material represented by Formula I consists of one liquid crystal material, and preferably a mixture of two or more liquid crystal materials. Preferably, there is provided a liquid crystal mixture comprising a liquid crystal material (alkyl-substituted liquid crystal material) in which R₁, of Formula I is substituted with a C₁˜C₂₀ alkyl group, a liquid crystal material (alkoxy-substituted liquid crystal material) in which R₁ is substituted with a C₁˜C₂₀ alkoxy group, and a liquid crystal material (alkylaryl-substituted liquid crystal material) in which R₁ is substituted with a C₁˜C₂₀ alkylaryl group. In this way, in the case where liquid crystal materials substituted with different functional groups are used in the form of a mixture, the alkyl-substituted liquid crystal material is used in an amount of 60˜90 wt %, the alkoxy-substituted liquid crystal material is used in an amount of 10˜30 wt %, and the alkylaryl-substituted liquid crystal material is used in an amount of 3˜15 wt %, based on the amount of the liquid crystal mixture.

As such, the alkyl-substituted liquid crystal material includes, for example, pentyl-substituted liquid crystal material and heptyl-substituted liquid crystal material, the alkoxy-substituted liquid crystal material includes octyloxy-substituted liquid crystal material, and the alkylaryl-substituted liquid crystal material includes pentylbenzyl-substituted liquid crystal material.

Particularly, in the present invention, the alkyl-substituted liquid crystal material includes 4-n-pentyl-4′-cyanobiphenyl, represented by Formula 1a below, or 4-n-heptyl-4′-cyanobiphenyl, represented by Formula 1b. The alkoxy-substituted liquid crystal material includes 4-n-octyloxy-4′-cyanobiphenyl, represented by Formula 1c below, and the alkylaryl-substituted liquid crystal material includes 4-pentyl-[1,1′;4′,1″]-terphenyl-4″-carbonitrile or 4-pentyl-[1,1′;4′,1″]-4″-cyanoterphenyl, represented by Formula 1d below:

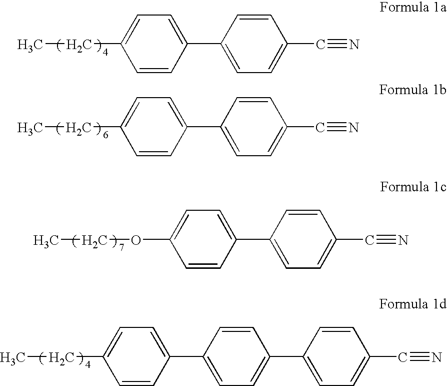

In the present invention, in the case where the low-molecular weight liquid crystal material is used in the form of a mixture, the liquid crystal material of Formula 1a is used in an amount of 35˜65 wt %, preferably 40˜60 wt %, the liquid crystal material of Formula 1b is used in an amount of 15˜35 wt %, preferably 20˜30 wt %, the liquid crystal material of Formula 1c is used in an amount of 10˜30 wt %, preferably, 15˜25 wt %, and the liquid crystal material of Formula id is used in an amount of 3˜15 wt %, preferably 5˜10 wt %, based on the total amount of the liquid crystal material. In this regard, particularly useful is E7, available from Merck KGaA, which is composed of 51 wt % of the material of Formula 1a, 25 wt % of the material of Formula 1b, 16 wt % of the material of Formula 1c, and 8 wt % of the material of Formula 1d.

In addition, the siloxane-based polymer liquid crystal material represented by Formula II or the acryl-based polymer liquid crystal material represented by Formula III has an average molecular weight of 5,000˜1,000,000.

Further, the siloxane-based polymer liquid crystal material is preferably exemplified by a polymer liquid crystal material, such as poly(4′-[(alkoxy)carbonyl]-phenylbenzoate-4-yloxyhexylmethylsiloxane) represented by Formula 2a below or poly(4′-cyano-biphenyl-4-yloxypropylmethylsiloxane) represented by Formula 2b below:

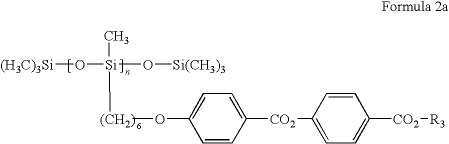

(in Formula 2a, R₃ is a linear or branched C₁˜C₁₀ alkyl group)

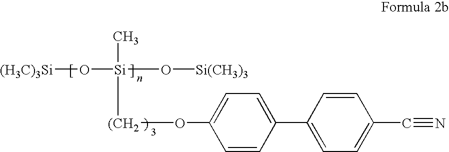

In the present invention, the material of Formula 2a includes poly(4′-[(2-methylbutoxy)carbonyl]-phenylbenzoate-4-yloxyhexylmethylsiloxane) as a siloxane-based polymer in which R₃ of Formula 2a is an isopentyl group, and is available from Merck KGaA under the trade name of LCP 1. Also, the material of Formula 2b includes poly(4′-[(2-methylbutoxy)carbonyl]-phenylbenzoate-4-yloxyhexyl methylsiloxane, and is available from Merck KGaA under the trade name of LCP 83.

Furthermore, the acryl-based polymer liquid crystal material of Formula III includes poly(4′-cyano-biphenyl-4-yloxycaronyldecyl methacrylate) represented by Formula 3a below, poly(4′-cyano-biphenyl-4-yloxypropyl acrylate) represented by Formula 3b below, or poly(4′-cyano-biphenyl-4-yloxycarbonylbutyl acrylate) represented by Formula 3c below:

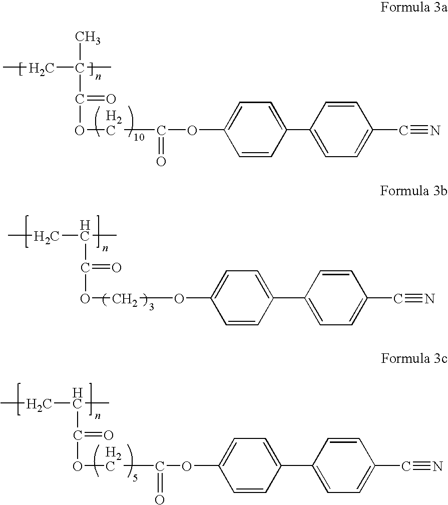

The materials of Formulas 3a to 3c are exemplified by LCP 94, LCP 95, and LCP 105, respectively, available from Merck KGaA.

The matrix component, that is, the matrix polymer and the liquid crystal material, is combined at a weight ratio of 1:30˜1:5 with the solvent contained in the electrolyte composition. According to the present invention, the matrix component may be used at a weight ratio of about 0.5˜2:1 with the ionic liquid used in the electrolyte composition.

In the solid-state dye-sensitized solar cell of the present invention, the second electrode 1005 functions as a cathode which is an electrode applied on the surface of the second substrate 1006. As such, using a sputtering process or a spin coating process the same as that used in the application of the first electrode 1002 on the surface of the first substrate 1001, the second electrode 1005 may be applied on the surface of the second substrate 1006.

The second electrode 1005 is formed of a material having a higher work function than that of the first electrode 1002, for example, platinum (Pt), gold, carbon, etc. Preferably, platinum is used.

The second substrate 1006 is formed of a transparent material similar to the first substrate 1001, for example, glass or plastic, PET (polyethylene terephthalate), PEN (polyethylene naphthelate), PP (polypropylene), PI (polyamide), TAC (tri acetyl cellulose), etc. Preferably, glass is used.

According to the present invention, the process of fabricating the solid-state dye-sensitized solar cell is described below.

First, colloidal titanium oxide, which is a type of inorganic oxide, is applied or cast on a first substrate coated with a first electrode material to a thickness of about 5˜30 μm and then sintered at about 200˜700□, and preferably 250˜600□, thus forming a photoelectrode comprising first substrate/first electrode/inorganic oxide, which are sequentially formed without the organic material. Subsequently, in order to adsorb a dye on the oxide layer, the dye, for example, Ruthenium 535, is added to an ethanol solution, which has been previously prepared, thus preparing a dye solution, after which the transparent substrate coated with the oxide layer (e.g., glass substrate coated with FTO, that is, photoelectrode) is dipped into the dye solution, whereby the dye is adsorbed on the oxide layer. After the completion of the adsorption of the dye on the oxide layer, the substrate is washed with ethanol to remove the physically adsorbed dye, and then dried.

When the transparent substrate coated with the oxide layer having the adsorbed dye is manufactured, an electrolyte solution including the liquid crystal material of the present invention is cast on the upper surface of the oxide layer using an adhesive frame made to a desired size. Thereafter, a platinum electrode, resulting from sintering of a platinum precursor material, is attached to the upper surface of the glass substrate, thereby fabricating the dye-sensitized solar cell of the present invention.

In such a case, in order to form the electrolyte solution containing the liquid crystal material on the surface of the photoelectrode having the first substrate/first electrode/oxide layer, which are sequentially formed, the photoelectrode including the dye-adsorbed inorganic oxide is dipped into the electrolyte solution containing the liquid crystal material for a predetermined period of time, such that the electrolyte solution is sufficiently absorbed by the pores of the inorganic oxide. Subsequently, the adhesive frame having a predetermined size is attached to the upper surface of the photoelectrode, and the electrolyte solution containing the liquid crystal material is uniformly applied on one surface of the oxide layer, after which the adhesive frame is removed, followed by a drying process.

The interfacial adhesion properties of the oxide layer, the dye and the electrolyte are determined by the solubility of the polymer in the electrolyte and the type of functional group thereof. The ionic conductivity of the electrolyte depends on the properties of the solvent and the type of additive. Of the constituents of the electrolyte, the binder, acting as the matrix, is exemplified by polyacrylonitrile (PAN), which is a conductive polymer having excellent properties, the terminal cyan group (—CN) thereof functioning to realize interfacial adhesion with the oxide layer and to orient the liquid crystal material, in particular, the low-molecular weight liquid crystal material.

The solid-state dye-sensitized solar cell of the present invention, in which the liquid crystal material is contained in the solid-state electrolyte layer in a predetermined proportion, has been confirmed to have greatly increased energy efficiency, compared to conventional solar cells. FIGS. 7 to 10 are graphs showing the magnitude of current depending on the applied voltage (current-voltage) among the electro-optical properties of the solid-state dye-sensitized solar cell, which is fabricated using the solid-state layer containing the liquid crystal material added in a predetermined proportion, in the preferred examples of the present invention.

In the respective graphs, the x axis is open-circuit voltage (V_{oc}), and the y axis is short-circuit current (I_{sc}) represented by the maximum threshold of voltage and current. The open-circuit voltage is the output voltage of the solar cell exposed to light under the opened circuit condition, that is, under the condition of infinite impedance or of current flow of 0. On the other hand, the short-circuit current is current flowing through the short-circuit upon radiation of light under the short-circuit condition, that is, under the condition of no external resistance or resistance of 0.

As shown in FIGS. 7 to 12, the solid-state dye-sensitized solar cell of the present invention, fabricated using the solid-state electrolyte containing the liquid crystal material added in a predetermined proportion, has excellent electro-optical properties. As a result of measurement of energy conversion efficiency, the solar cell of the present invention is confirmed to have energy conversion efficiency superior to conventional dye-sensitized solar cells.

A better understanding of the present invention may be obtained through the following examples which are set forth to illustrate, but are not to be construed as the limit of the present invention.

### EXAMPLE 1

### Preparation of Dye-Adsorbed Oxide Layer

A colloidal titanium oxide paste having a particle size of 9 nm was thinly applied to a thickness of about 10 μm using a doctor blade process on a glass substrate coated with FTO (Fluorine doped tin oxide, SnO₂:F, 15 ohm/sq), which was cut to a size of 15 mm×15 mm and then washed, placed in an electric furnace to heat it from room temperature to 450□ and maintain that temperature for about 30 min so as to remove the organic material, and then cooled to room temperature. The heating rate and the cooling rate were about 5□ per min. The substrate coated only with titanium oxide without the organic material was dipped into a dye solution at room temperature for 24 hours, thus adsorbing the dye on the titanium oxide layer. The dye used was cis-bis(isothiocyanato)bis(2,2′-bipyridyl-4,4′-dicarboxylato)-ruthenium (II), (Ruthenium 535), available from Solaronix, Switzerland. The Ruthenium 535 dye solution was prepared by dissolving 20 mg of the Ruthenium 535 in 100 mL of ethanol. The substrate coated with titanium oxide was dipped into the dye solution for 24 hours, after which the dye-adsorbed titanium oxide substrate was removed from the dye solution, washed with ethanol to remove a physically adsorbed dye layer, and then dried at 60□, thus manufacturing a dye-adsorbed titanium oxide substrate.

### EXAMPLE 2

### Measurement of UV-VIS Absorption Spectrum of

Dye-Adsorbed Titanium Oxide Substrate The absorbance of the dye-adsorbed titanium oxide substrate manufactured in Example 1 was measured using a UV-visible spectrometer. For comparison of the absorbance, the absorption spectrum of the titanium oxide substrate before being adsorbed with the dye was measured along with the absorption spectrum of the dye solution before adsorption. The measurement was conducted using an OPTIZEN 2120 UV/VIS spectrometer (Mecasys Co., Ltd.). The results of UV-visible absorption spectrum are shown in FIG. 2.

As shown in FIG. 2, when the dye-adsorbed titanium oxide layer of Example 1 was compared with the titanium oxide layer before being adsorbed with the dye, the titanium oxide layer before being adsorbed with the dye had a UV maximum absorption peak of about 330 nm, mainly corresponding to the UV region, whereas the dye-adsorbed titanium oxide layer was observed to have UV maximum absorption peaks of about 350 nm, 410 nm and 550 nm, corresponding to the visible region, thus having wider absorption wavelengths. The maximum absorption peak of the dye in a state of the solution before adsorption was only slightly changed, compared to that of the dye after adsorption. However, the absorbance of the dye-adsorbed titanium oxide layer was greatly increased, which is believed to be due to the adsorption of the dye.

### EXAMPLE 3

### Measurement of Cross-Section and Surface of Dye-Adsorbed Titanium Oxide Substrate Using SEM

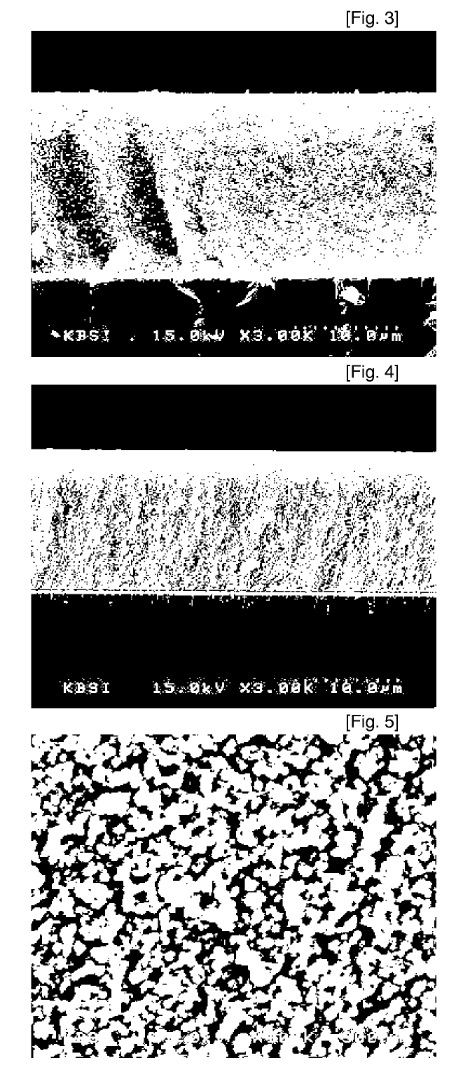

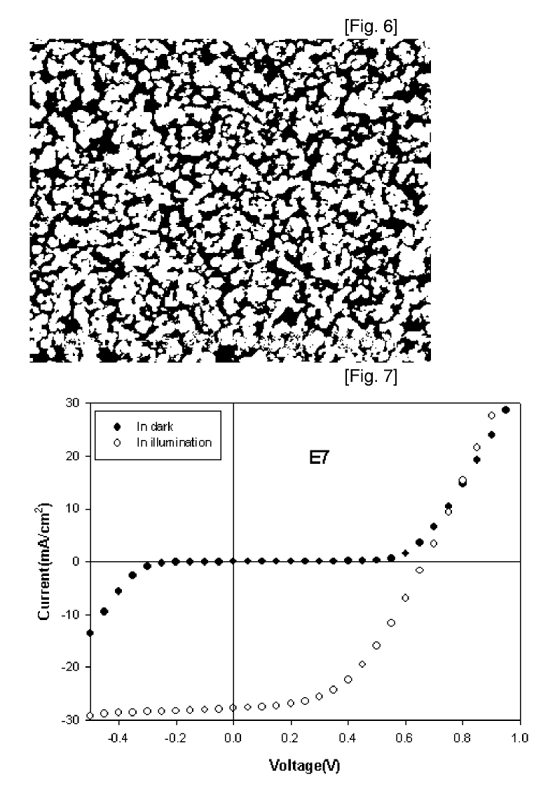

The morphologies of the surface and cross-section of the titanium oxide layer and the dye-adsorbed titanium oxide layer of Example 1 were measured using SEM (Hitachi S4200). FIGS. 3 and 4 are SEM photographs showing the cross-sections of the titanium oxide layer and the dye-adsorbed titanium oxide layer, respectively. FIGS. 5 and 6 are SEM photographs showing the surfaces of the titanium oxide layer and the dye-adsorbed titanium oxide layer, respectively.

As is apparent from the result of observation using SEM, titanium oxide was confirmed to be porous nanocrystalline. Particularly, in the case of the dye-adsorbed titanium oxide layer, it was confirmed to have a smaller pore size than the titanium oxide layer before the adsorption of the dye. In addition, the titanium oxide layer before the adsorption of the dye was seen to be uniformly applied to a thickness of about 10 μm. Even after the adsorption of the dye, it was confirmed that the applied thickness was similar and the surface was uniformly formed.

### EXAMPLE 4

### Preparation of Electrolyte Solution Including Liquid Crystal

0.04 g of polyacrylonitrile, which is a matrix polymer acting as a polymer binder, and 0.04 g of E7, available from Merck KGaA, were used. As a redox couple, TBAI/I₂ were used in amounts of 0.072 g and 0.024 g, respectively, and as a plasticizer, ethylene carbonate/propylene carbonate were added at a ratio (1:4) of 0.423 g (0.32 mol) and 0.095 g (0.08 mol). Subsequently, 0.08 g of 1-ethyl-3-methylimidazolium iodide was added as an ionic liquid to increase the ionic conductivity.

Then, the low-molecular weight liquid crystal composition, commercially available as E7 from Merck KGaA, was added at the same weight proportion as the polyacrylonitrile, dissolved in acetonitrile (0.314 g, 0.4 mol), and stirred at room temperature for 24 hours, thus preparing an electrolyte solution.

### EXAMPLE 5

### Preparation of Electrolyte Solution Including Liquid Crystal

An electrolyte solution was prepared in the same manner as in Example 4, with the exception that a siloxane-based liquid crystal compound, commercially available as LCP 1 and LCP 83, and an acryl-based liquid crystal compound, commercially available as LCP 94, LCP 95 and LCP 105, were used as the liquid crystal material contained in the electrolyte.

### EXAMPLE 6

### Preparation of Electrolyte Solution Including Liquid Crystal

An electrolyte solution was prepared in the same manner as in Example 4, with the exception that the polyacrylonitrile, as the matrix polymer, and the E7, as the low-molecular weight liquid crystal material, were used at a weight ratio of 25:75.

### EXAMPLE 7

### Preparation of Electrolyte Solution Including Liquid Crystal

An electrolyte solution was prepared in the same manner as in Example 4, with the exception that the polyacrylonitrile, as the matrix polymer, and the E7, as the low-molecular weight liquid crystal material, were used at a weight ratio of 75:25.

### EXAMPLE 8

### Fabrication of Solid-State Electrolyte Layer Using Electrolyte Solution

The dye-adsorbed titanium oxide substrate manufactured in Example 1 was dipped into each electrolyte solution of Examples 4 and 5 at room temperature for 24 hours. When the electrolyte solution was sufficiently absorbed by the titanium oxide pores, the substrate was washed. Subsequently, an adhesive tape in the shape of a frame having a size of 5 mm×5 mm was attached to the upper surface of the substrate, after which the electrolyte solution of Example 4 was uniformly applied using a spoid. After the electrolyte solution was slightly dried, the adhesive tape was removed, and the substrate was placed into an oven to dry it at about 50˜600 for 2˜3 hours.

### EXAMPLE 9

### Fabrication of Solid-State Electrolyte Layer Using Electrolyte Solution

A solid-state electrolyte layer was manufactured in the same manner as in Example 8, with the exception that the electrolyte solution prepared in Example 6 was used.

### EXAMPLE 10

### Fabrication of Solid-State Electrolyte Layer Using Electrolyte Solution

A solid-state electrolyte layer was manufactured in the same manner as in Example 8, with the exception that the electrolyte solution prepared in Example 7 was used.

### EXAMPLE 11

### Fabrication of Platinum Electrode

In order to fabricate a transparent dye-sensitized solar cell, a paste containing a platinum precursor was used. As such, the paste containing a platinum precursor was purchased from Solaronix, Switzerland.

Through the same process as in the preparation of the titanium oxide layer in Example 1, an FTO glass substrate cut to a size of 15 mm×10 mm was coated with platinum using the paste containing a platinum precursor heated to 400□ from room temperature. The thickness of the platinum electrode thus formed was measured to be about 100 nm using an alpha step.

### EXAMPLE 12

### Fabrication of Solid-State Dye-Sensitized Solar Cell

On the dye-adsorbed titanium oxide of Examples 4 and 5, the 5 mm×5 mm sized electrode substrate coated with each liquid crystal material-containing solid-state electrolyte of Example 8 was attached to the platinum electrode substrate of Example 10, thus fabricating the solid-state dye-sensitized solar cell.

### EXAMPLE 13

### Fabrication of Solid-State Dye-Sensitized Solar Cell

A solid-state dye-sensitized solar cell was fabricated in the same manner as in Example 12, with the exception that the solid-state electrolyte layer of Example 9 was used.

### EXAMPLE 14

### Fabrication of Solid-State Dye-Sensitized Solar Cell

A solid-state dye-sensitized solar cell was fabricated in the same manner as in Example 12, with the exception that the solid-state electrolyte layer of Example 10 was used.

### EXAMPLE 15

### Measurement of Electro-Optical Properties of Solid-State Dye-Sensitized Solar Cell

The electro-optical properties of the solid-state dye-sensitized solar cells of Example 12 were measured.

The voltage-current density of the solid-state dye-sensitized solar cell including each liquid crystal material-containing electrolyte of Example 12 was measured using a Keithley 236 Source Measurement and Solar Simulator (300 W simulator models 81150 and 81250, Spectra-physics Co.) under standard conditions (AM 1.5, 100 mW/cm², 25□). The results of measurement of the voltage-current density of the solar cell including respective liquid crystal materials are shown in FIGS. 7 to 12.

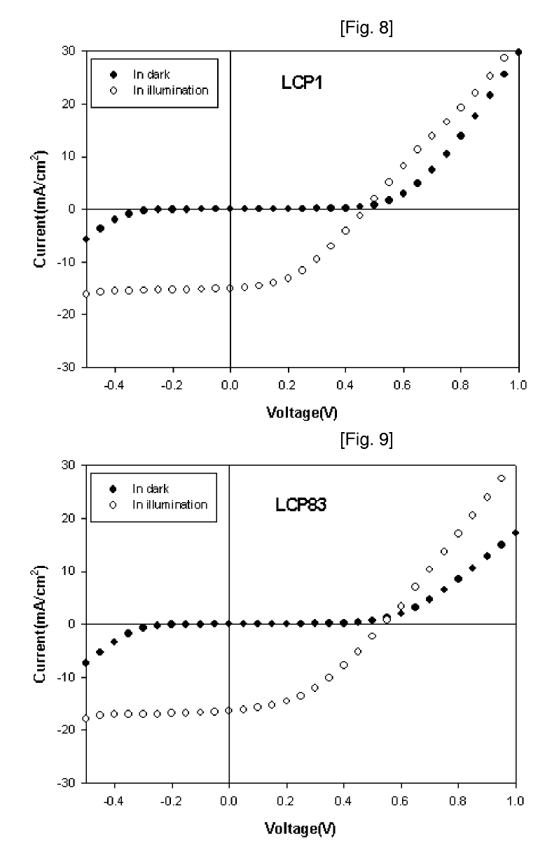

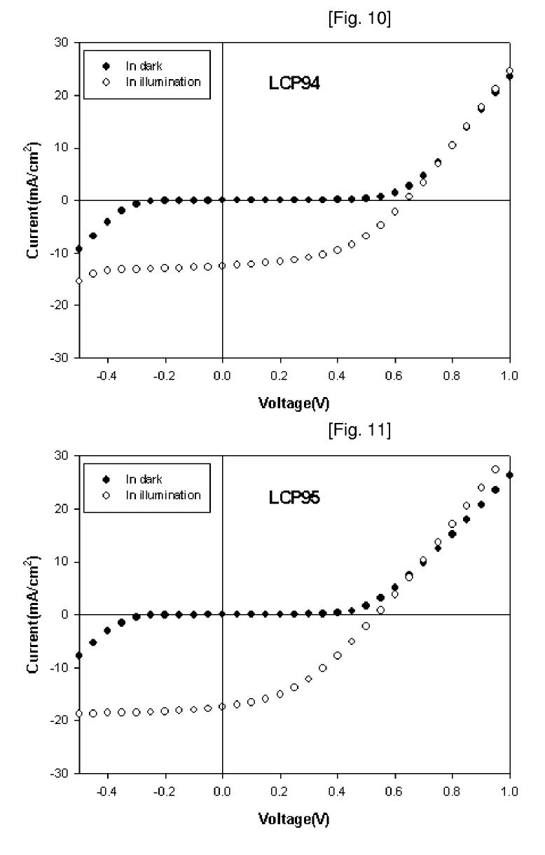

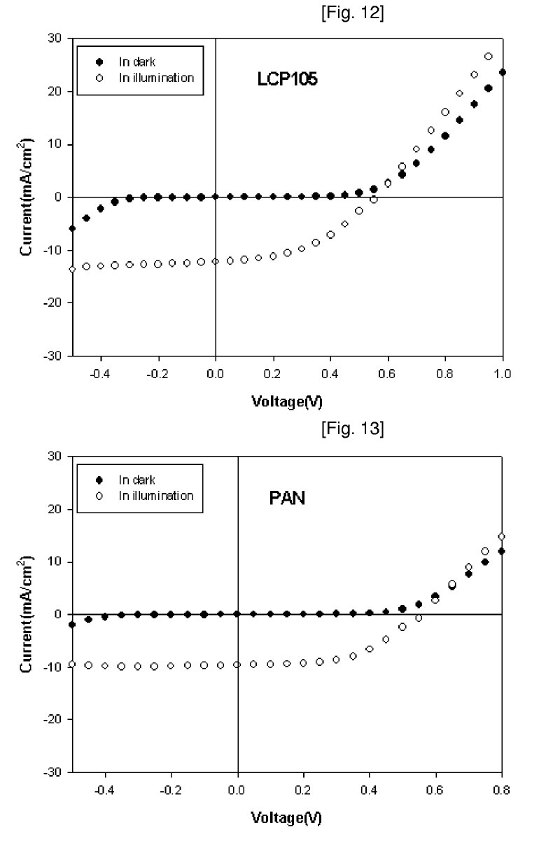

FIGS. 7 to 12 are graphs showing the magnitude of current density depending on the applied voltage of the dye-sensitized solar cell including the electrolyte having E7 (FIG. 7) as the low-molecular weight liquid crystal mixture, LCP 1 (FIG. 8) and LCP 83 (FIG. 9) as the siloxane-based polymer liquid crystal material, and LCP 94 (FIG. 10), LCP 95 (FIG. 11), and LCP 105 (FIG. 12) as the acryl-based polymer liquid crystal material.

As shown in the drawings, the solar cell fabricated by adding the low-molecular weight liquid crystal mixture E7 or the polymer liquid crystal material LCP 1, LCP 83, LCP 94, LCP 95, or LCP 105 to the electrolyte had an open-circuit voltage of about 0.5˜0.6 V and a short-circuit current of 12˜27 mA/cm².

Particularly, the dye-sensitized solar cell in which the low-molecular weight liquid crystal mixture E7 was added to the electrolyte had energy conversion efficiency of 8.9%. Although the dye-sensitized solar cell containing the siloxane- or acryl-based polymer liquid crystal material had lower energy conversion efficiency than the low-molecular weight liquid crystal-containing solar cell, it exhibited energy conversion efficiency of about 3%, which is superior to conventional solid-state dye-sensitized solar cells.

The open-circuit voltage, the short-circuit current, the fill factor and the energy conversion efficiency of the dye-sensitized solar cell containing respective liquid crystal materials are summarized in Table 1 below.

TABLE 1
Electro-optical Properties of Solar Cell using Solid-state Electrolyte
having Polymer and Liquid Crystal (at weight ratio of 50:50)

| | Open- | Short- | | Energy |
|---|---|---|---|---|
| | Circuit | Circuit | Fill | Conversion |
| Liquid | Voltage | Current | Factor* | Efficiency** |
| Crystal | (V_{oc}) (V) | (I_{sc}) (mA/cm²) | (FF) | (%) |
| E7 | 0.66 | 27.80 | 0.49 | 8.93 |
| LCP 1 | 0.47 | 15.05 | 0.41 | 2.90 |
| LCP 83 | 0.54 | 16.43 | 0.41 | 3.60 |
| LCP 94 | 0.64 | 12.52 | 0.48 | 3.82 |
| LCP 95 | 0.52 | 15.80 | 0.42 | 3.46 |
| LCP 105 | 0.56 | 12.20 | 0.45 | 3.06 |

*voltage at maximum power (Vₘₚ) × current at maximum power (Iₘₚ)/(V_{oc} × I_{sc})
**FF × {(I_{sc} × V_{oc})/Pin}, Pin = 100 [mW/cm²]

### EXAMPLE 16

The solid-state dye-sensitized solar cell of Example 13 was treated with the same process and conditions as those of Example 15, thus fabricating a solar cell, which was then measured with respect to the electro-optical properties. The results are given in Table 2 below.

TABLE 2
Electro-optical Properties of Solar Cell using Solid-state Electrolyte
having Polymer and Liquid Crystal (at weight ratio of 25:75)

| | Open- | Short- | | Energy |
|---|---|---|---|---|
| | Circuit | Circuit | Fill | Conversion |
| Liquid | Voltage | Current | Factor* | Efficiency** |
| Crystal | (V_{oc}) (V) | (I_{sc}) (mA/cm²) | (FF) | (%) |
| E7 | 0.61 | 15.49 | 0.46 | 4.41 |

*voltage at maximum power (Vₘₚ) × current at maximum power (Iₘₚ)/(V_{oc} × I_{sc})
**FF × {(I_{sc} × V_{oc})/Pin}, Pin = 100 [mW/cm²]

### EXAMPLE 17

The solid-state dye-sensitized solar cell of Example 14 was treated with the same process and conditions as those of Example 15, thus fabricating a solar cell, which was then measured with respect to the electro-optical properties. The results are given in Table 3 below.

TABLE 3.
Electro-optical Properties of Solar Cell using Solid-state Electrolyte
having Polymer and Liquid Crystal (at weight ratio of 75:25)

| | Open- | Short- | | Energy |
|---|---|---|---|---|
| | Circuit | Circuit | Fill | Conversion |
| Liquid | Voltage | Current | Factor* | Efficiency** |
| Crystal | (V_{oc}) (V) | (I_{sc}) (mA/cm²) | (FF) | (%) |
| E7 | 0.61 | 15.30 | 0.47 | 4.36 |

*voltage at maximum power (Vₘₚ) × current at maximum power (Iₘₚ)/(V_{oc} × I_{sc})
**FF × {(I_{sc} × V_{oc})/Pin}, Pin = 100 [mW/Cm²]

### Comparative Example

### Measurement of Electro-Optical Properties of Solid-State Dye-Sensitized Solar Cell without Liquid Crystal

Instead of the solid-state dye-sensitized solar cell using the electrolyte having the liquid crystal material of the present invention, a conventional solid-state dye-sensitized solar cell having no liquid crystal material was measured with respect to the electro-optical properties thereof.

The electrolyte solution was prepared in the same manner as in Example 4 with the exception that the liquid crystal material was not added, leading to a solid-state dye-sensitized solar cell. Such a solid-state dye-sensitized solar cell having no liquid crystal material was measured with respect to the magnitude of current density depending on the voltage under the same conditions as Example 15. The result of measurement of the voltage-current of the conventional solid-state dye-sensitized solar cell fabricated in the comparative example is shown in FIG. 13. In addition, the open-circuit voltage, the short-circuit current, the fill factor and the energy conversion efficiency thereof are summarized in Table 4 below.

In the conventional solid-state dye-sensitized solar cell, the open-circuit voltage determined by the band gap energy difference of two electrodes was similar to that of the solar cell containing the liquid crystal material of Example 11. However, the short-circuit current thereof, determined by the flow of photocurrent and the ionic conductivity depending on excellent interfacial contact, was only 9.65 mA/cm², which was much lower than that of the solar cell using the liquid crystal material-containing electrolyte. Thereby, the energy conversion efficiency was lower, compared to that of the solar cell containing the liquid crystal material.

TABLE 4
Electro-optical Properties of Conventional
Dye-sensitized Solar Cell

| | Open- | Short- | | Energy |
|---|---|---|---|---|
| | Circuit | Circuit | Fill | Conversion |
| | Voltage | Current (I_{sc}) | Factor* | Efficiency** |
| Polymer | (V_{oc}) (V) | (mA/cm²) | (FF) | (%) |
| Polyacrylonitrile | 0.56 | 9.65 | 0.51 | 2.78 |
| (PAN) | | | | |

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A solid-state electrolyte, comprising:
a matrix component, including at least one low-molecular weight liquid crystal material represented by Formula I below, or a polymer liquid crystal material selected from a siloxane-based polymer liquid crystal material represented by Formula II below and an acryl-based polymer liquid crystal material represented by Formula III below, and a matrix polymer; and
an electrolyte composition: 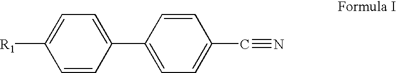
(in Formula I, R₁ is a C₁˜C₂₀ alkyl group, a C₁˜C₂₀ alkoxy group, or a C₁˜C₂₀ alkylaryl group) 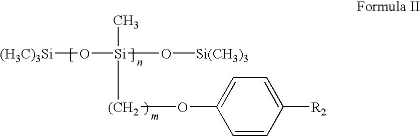
(in Formula II, R₂ is an unsubstituted or substituted aryl group, m is an integer of 1˜20, and n is an integer of 10 or more) 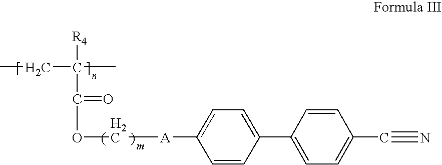
(in Formula III, R₄ is hydrogen or a C₁˜C₁₀ alkyl group, A is ether, ester, or a ketone group, m is an integer of 1˜20, and n is an integer of 10 or more)

2. The electrolyte according to claim 1, wherein the liquid crystal material is included in an amount of 5˜95 wt %, based on an amount of the matrix component.

3. The electrolyte according to claim 1, wherein the low-molecular weight liquid crystal material represented by Formula I is a liquid crystal mixture comprising liquid crystal material (alkyl-substituted liquid crystal material) in which R₁ is substituted with a C₁˜C₂₀ alkyl group, liquid crystal material (alkoxy-substituted liquid crystal material) in which R₁ is substituted with a C₁˜C₂₀ alkoxy group, and liquid crystal material (alkylaryl-substituted liquid crystal material) in which R₁ is substituted with a C₁˜C₂₀ alkylaryl group.

4. The electrolyte according to claim 3, wherein the alkyl-substituted liquid crystal material is included in an amount of 60˜90 wt %, the alkoxy-substituted liquid crystal material is included in an amount of 10˜30 wt %, and the alkylaryl-substituted liquid crystal material is included in an amount of 3˜15 wt %, based on an amount of the liquid crystal mixture.

5. The electrolyte according to claim 3, wherein the alkyl-substituted liquid crystal material is 4-n-pentyl-4′-cyanobiphenyl or 4-n-heptyl-4′-cyanobiphenyl, the alkoxy-substituted liquid crystal material is 4-n-octyloxy-4′-cyanobiphenyl, and the alkylaryl-substituted liquid crystal material is 4-pentyl-[1,1′;4′,1″]-4″-carbonitrile.

6. The electrolyte according to claim 5, wherein the 4-n-pentyl-4′-cyanobiphenyl is included in an amount of 35˜65 wt %, the 4-n-heptyl-4′-cyanobiphenyl is included in an amount of 15˜35 wt %, the 4-n-octyloxy-4′-cyanobiphenyl is included in an amount of 10˜30 wt %, and the 4-pentyl-[1,1′;4′,1″]-4″-carbonitrile is included in an amount of 3˜15 wt %, based on an amount of the liquid crystal mixture.

7. The electrolyte according to claim 1, wherein the siloxane-based polymer liquid crystal material or the acryl-based polymer liquid crystal material has an average molecular weight of 5,000˜1,000,000.

8. The electrolyte according to claim 1, wherein the siloxane-based polymer liquid crystal material comprises a polymer represented by Formula 2a or 2b below: 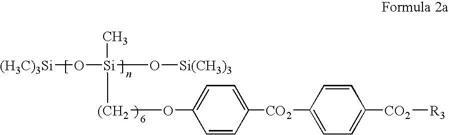
(in Formula 2a, R₃ is a linear or branched C₁˜C₁₀ alkyl group)

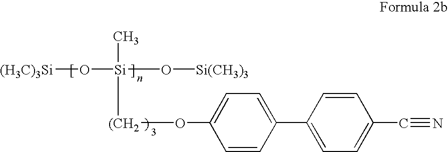

9. The electrolyte according to claim 1, wherein the acryl-based polymer liquid crystal material comprises poly(4′-cyano-biphenyl-4-yloxycarbonyldecyl methacrylate), poly(4′-cyano-biphenyl-4-yloxypropyl acrylate), or poly(4′-cyano-biphenyl-4-yloxycarbonylbutyl acrylate).

10. The electrolyte according to claim 1, wherein the electrolyte composition comprises a solvent and a redox couple dissolved in the solvent.

11. The electrolyte according to claim 10, wherein the matrix polymer is combined at a weight ratio of 1:30˜1:5 with the solvent.

12. A dye-sensitized solar cell, comprising:
a first electrode;
a second electrode facing the first electrode;
an oxide layer having a dye adsorbed thereon and formed between the first electrode and the second electrode; and
a solid-state electrolyte layer formed adjacent to the oxide layer, including a matrix component having at least one low-molecular weight liquid crystal material represented by Formula I below, or a polymer liquid crystal material selected from a siloxane-based polymer liquid crystal material represented by Formula II below and an acryl-based polymer liquid crystal material represented by Formula III below, and an electrolyte composition: 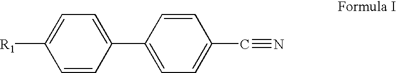
(in Formula I, R₁ is a C₁˜C₂₀ alkyl group, a C₁˜C₂₀ alkoxy group, or a C₁˜C₂₀ alkylaryl group) 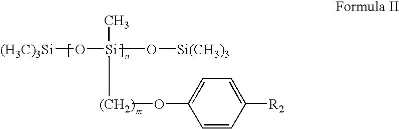
(in Formula II, R₂ is an unsubstituted or substituted aryl group, m is an integer of 1˜20, and n is an integer of 10 or more) 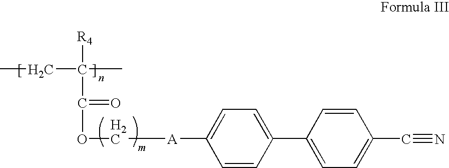
(in Formula III, R₄ is hydrogen or a C₁˜C₁₀ alkyl group, A is ether, ester, or a ketone group, m is an integer of 1˜20, and n is an integer of 10 or more).

13. The solar cell according to claim 12, wherein the first electrode is formed of ITO (indium-tin oxide), FTO (Fluorine doped tin oxide), ZnO—(Ga₂O₃ or Al₂O₃), or SnO₂—Sb₂O₃.

14. The solar cell according to claim 12, wherein the second electrode is formed of platinum, gold, or carbon.

15. The solar cell according to claim 12, wherein the oxide layer is a transition metal oxide layer.
